(19) United States
(12) Patent Application Publication
(10) Pub. No.: US 2024/0375132 A1
(43) Pub. Date: Nov. 14, 2024

(54) DROPLET APPLICATOR AND METHOD FOR GENERATING MOLTEN METAL DROPLETS

(71) Applicant: Robert Bosch GmbH, Stuttgart (DE)

(72) Inventor: Holger Wuest, Waldenbuch (DE)

(21) Appl. No.: 18/557,479

(22) PCT Filed: Apr. 22, 2022
(86) PCT No.: PCT/EP2022/060711

§ 371 Date: Dec. 22, 2023

(30) Foreign Application Priority Data
Apr. 29, 2021 (DE) 10

(51) Int. Cl. B05B 7/18; B05B 7/22; H01L 21/768

(52) U.S. Cl. CPC B05B 7/18; B05B 7/22; H01L 21/76877

(57) ABSTRACT

A droplet applicator for generating molten metal droplets having a volume in the range of nanoliters to milliliters. The droplet applicator includes a first wire feeding device, which vertically moves a first wire including a first wire material, and a first wire blocking device, which is configured to block the first wire. The first wire feeding device and the first wire blocking device are arranged within a housing, A wire heating device is arranged, vertically flush, below the first wire feeding device. The wire heating device heats regions of the first wire that have been introduced into the wire heating device by the first wire feeding device, to a temperature above a melting temperature of the first wire material.

### FIELD

The present invention relates to a droplet applicator and to a method for generating molten metal droplets, and to a use of the droplet applicator for filling a rear cavity of a semiconductor component.

### BACKGROUND INFORMATION

Vertical semiconductor components in which heteroepitaxial layers of SiC or GaN are applied onto a foreign substrate require cavities on the rear side with an extension of a few millimeters for the electric current flow. In order to be able to ensure the stability of the semiconductor component and an electrical connection, these cavities must be filled with a metal.

It is disadvantageous here that such large cavities cannot be filled cost-effectively, quickly and selectively with conventional coating devices and electroplating devices of the semiconductor industry.

An object of the present invention is to overcome these disadvantages.

### SUMMARY

According to an example embodiment of the present invention, a droplet applicator is provided for generating molten metal droplets having a volume in the range of nanoliters to milliliters which comprises a first wire feeding device and a first wire blocking device. The first wire feeding device vertically moves a first wire comprising a first wire material. The first wire blocking device is configured to block the first wire. The first wire feeding device and the first wire blocking device are arranged within a housing. According to an example embodiment of the present invention, a wire heating device is arranged, vertically flush, below the first wire feeding device, wherein the wire heating device heats regions of the first wire that have been introduced into the wire heating device by the first wire feeding device, to a temperature above a melting temperature of the first wire material.

An advantage here is that regions of a workpiece can be filled in a quick and target manner at high density.

In one development of the present invention, a second wire feeding device is arranged at a horizontal distance from the first wire feeding device. The horizontal direction is here arranged perpendicularly to the vertical direction. The second wire feeding device vertically moves the second wire, wherein a diameter of the first wire and a diameter of the second wire are different from one another. The wire heating device can be moved horizontally. In other words, it may be arranged flush with the first wire feeding device or with the second wire feeding device.

It is advantageous here that the amount of the molten wire material can be adapted to the circumstances of a workpiece to be filled.

In one development of the present invention, the wire heating device is an induction coil.

An advantage here is that the melting of the wire occurs only locally in the field of action of the induction coil.

In a further embodiment of the present invention, the wire heating device is a pointed surface that can be heated via an electrical resistance. In other words, the wire heating device resembles a soldering iron.

It is advantageous here that the pointed surface can be positioned close to the workpiece to be filled, so that the molten metal droplets can be dispensed in a targeted manner.

In one development of the present invention, the pointed surface comprises tungsten, carbon or ceramic.

An advantage here is that the pointed surface can withstand high temperatures.

In a further embodiment of the present invention, a suction device is arranged within the housing and is configured to extract gases that arise during melting of the first wire and/or of the second wire.

It is advantageous here that the gaseous portions of the alloy elements that arise during melting do not affect or contaminate the semiconductor processes.

In one development of the present invention, a closure is arranged at a vertical distance below the wire heating device, wherein the closure can be moved horizontally.

An advantage here is that contamination of the semiconductor structure to be filled by falling abraded material due to the movement of the wire device or by molten droplets released too late from the droplet applicator is prevented.

In a further embodiment of the present invention, the first wire material and/or the second wire material is copper.

It is advantageous here that copper is highly conductive.

The droplet applicator according to the present invention may be used for filling rear cavities of a semiconductor component.

An advantage here is that large rear cavities having a lateral extension in the millimeter range are filled cost-effectively, quickly and selectively. Furthermore, the maximum heat input by the molten droplets into the workpiece to be filled is less than the filling by fusion casting.

A method according to an example embodiment of the present invention for generating a molten metal droplet comprises introducing regions of a first wire from a first wire material by means of a wire feeding device into a wire heating device and heating the regions of the first wire to a temperature above a melting temperature of the first wire material by means of the wire heating device, which is in particular operated with a high-frequency alternating field.

Further advantages emerge from the following description of exemplary embodiments of the present invention, and the rest of the disclosure herein.

### BRIEF DESCRIPTION OF THE DRAWINGS

The present invention is explained below with reference to preferred embodiments and the figures.

FIG. 1 shows a first exemplary embodiment of a droplet applicator according to the present invention for generating molten metal droplets,

FIG. 2 shows a second exemplary embodiment of the droplet applicator according to the present invention for generating molten metal droplets,

FIG. 3 shows a method according to an example embodiment of the present invention for generating molten metal droplets.

FIG. 4 shows a use of the droplet applicator according to an example embodiment of the present invention.

### DETAILED DESCRIPTION OF EXAMPLE EMBODIMENTS

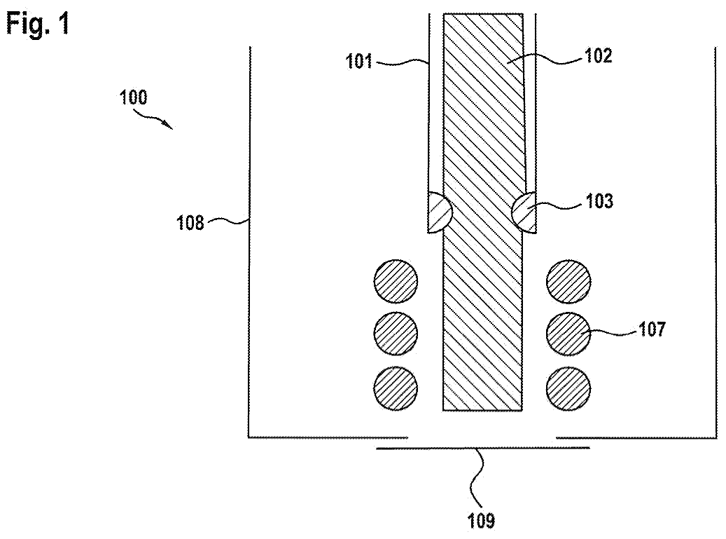

FIG. 1 shows a first exemplary embodiment of a droplet applicator 100 according to the present invention for generating molten metal droplets, i.e., the generated droplets consist of molten metal. The droplet applicator 100 comprises a first wire feeding device 101, a first wire blocking device 103, a wire heating device 107, a housing 108, and a closure 109. The first wire feeding device 101, the first wire blocking device 103 and the wire heating device 107 are arranged within the housing 108, wherein the wire heating device 107 is arranged, vertically flush, at a distance below the first wire feeding device 103. The first wire blocking device 103 is arranged at an end of the first wire feeding device 101 facing the wire heating device 107. The first wire feeding device 101 is configured to move or transport a first wire 102. The first wire blocking device 103 is configured to block the first wire 102 as soon as a specific amount or a region of the first wire 102 has been introduced into the wire heating device 107. The closure 109 is arranged at a distance below the wire heating device 107 and can be moved horizontally. The horizontal direction is arranged perpendicularly to the vertical direction.

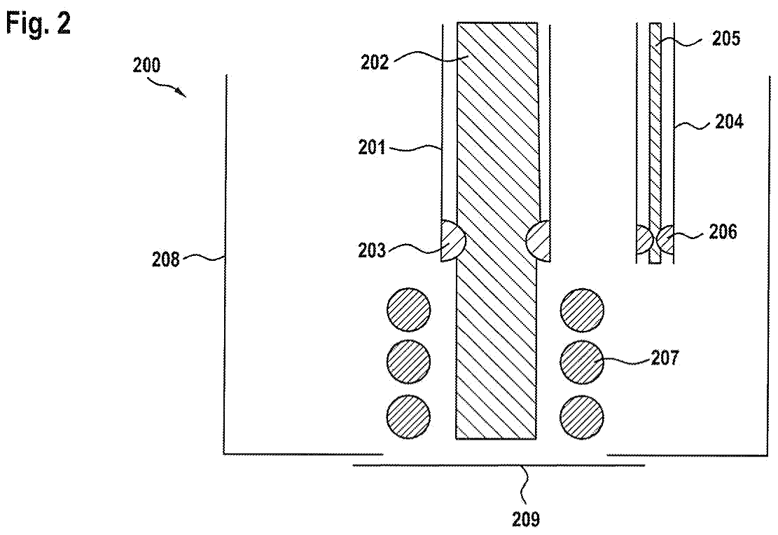

FIG. 2 shows a second exemplary embodiment of the droplet applicator 200 according to the present invention. The droplet applicator 200 comprises a first wire feeding device 201, a first wire blocking device 203, a second wire feeding device 204, a second wire blocking device 206, and a wire heating device 207, which are arranged within a housing 208. The housing 208 comprises a closure 209 which is arranged at a distance below the wire heating device 207 and can be moved horizontally. The first wire feeding device 201 is arranged at a horizontal distance from the second wire feeding device 204. The wire heating device 207 is arranged at a vertical distance below the first wire feeding device 201 and the second wire feeding device 204. The wire heating device 207 can be moved horizontally so that it can be arranged flush below the first wire heating device 201 or the second wire heating device 204. The first wire blocking device 203 and the second wire blocking device 206 are arranged at an end, facing the wire heating device 207, of the first wire feeding device 201 and of the second wire feeding device 204, respectively. The first wire feeding device 201 and the second wire feeding device 204 move the first wire 202 and the second wire 205, respectively, wherein a diameter of the first wire 202 and a diameter of the second wire 205 are different from one another. The diameter of the first wire 202 comprises a range of 50 μm to 200 μm, for example. The diameter of the second wire 205 comprises a range of 0.1 μm to 10 μm, for example. The dimensions of the first wire feeding device 201 and of the second wire feeding device 204 may be different from one another. The first wire blocking device 203 and the second wire blocking device 206 have a feed mechanism that unblocks or blocks the first wire 202 and the second wire 205, respectively. In this case, the wire supply is blocked as soon as a specific amount or a region of the first wire 202 or of the second wire 205 has been introduced into the wire heating device 207.

The first wire feeding device 101 and 201 and the second wire feeding device 204 are, for example, driven by means of micromotors, wherein the first wire 102 and 202 or the second wire 205 are pulled from a roll and pushed into the wire heating device 107 and 207 via conveyor rollers.

In one exemplary embodiment, the wire heating device 107 and 207 is an induction coil. The induction coil is operated with a high-frequency alternating field so that electrical eddy currents are induced in the regions of the first wire 102 and 202 and of the second wire 205 that have been introduced into the induction coil. In this way, the regions of the first wires 102 and 202 and of the second wire 205 are heated by means of heat dissipation and melt, wherein liquid molten metal droplets are formed. The melting takes place only in the wire region that is located in the field of action or in the volume of action of the induction coil. The high-frequency alternating field is applied until the wire volume within the induction coil is melted. Due to its weight force, the metal droplet in molten form detaches from the non-molten region within the wire feeding devices and falls downward. The molten volume can in this case be controlled via the height of the induction coil.

In a further exemplary embodiment, the wire heating device 107 and 207 comprises a pointed surface that can be heated via an electrical resistance. The mode of operation of the pointed surface resembles the mode of operation of a soldering iron. The pointed surface comprises a heat-resistant material having a melting point higher than the material to be melted of the first wire 102 and 202 or of the second wire 205, e.g., tungsten, carbon or ceramic. The heated pointed surface is guided into the region of the first wire 102 and 202 and of the second wire 205 that is located outside the first wire feeding device 101 and 201 and the second wire feeding device 204, respectively. The region of the first wire 102 and 202 and of the second wire 205 are melted by means of heat transfer. The molten metal droplets detach due to rapid movement of the pointed surface so that the molten metal droplets fall downward.

The droplet applicator 100 and 200 may additionally comprise a suction device 108 and 208. It is used to extract the gases arising during heating and melting of the first wire 102 and 202 and/or of the second wire 205. The suction device 108 and 208 is, for example, arranged laterally next to the first wire feeding device 101 or between the first wire feeding device 201 and the second wire feeding device 204.

The droplet applicator 100 and 200 is used in wafer semiconductor processes and in other metallization processes with nanoscale or microscale dimensions.

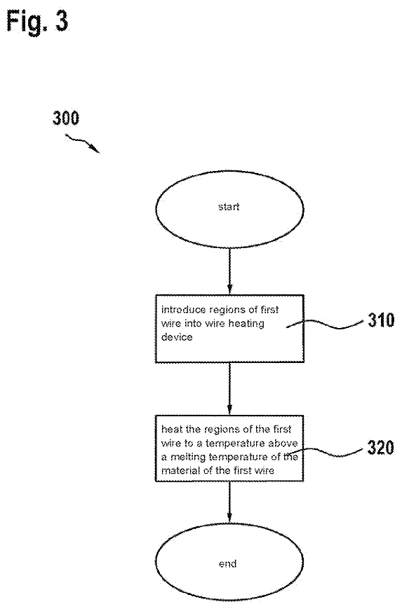

FIG. 3 shows a method 300 according to the present invention for generating molten metal droplets. The method 300 starts with a step 310 in which regions of a first wire made of a first wire material are introduced into a wire heating device by means of a first wire feeding device. In a following step 320, the regions of the first wire are heated to a temperature above a melting temperature of the first wire material by means of the wire heating device, which is in particular operated with a high-frequency alternating field. The high-frequency alternating field has a frequency that is adapted to the diameter of the wires to be heated. The frequency may be less than 500 Hz for wire diameters in the mm range and greater than 500 Hz for wire diameters in the μm range.

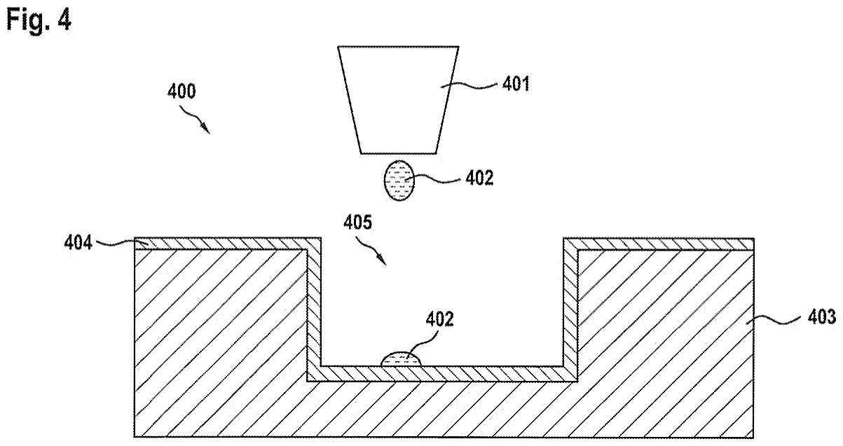

FIG. 4 shows a use 400 of the droplet applicator 401 according to the present invention. The droplet applicator 401 is arranged above a cavity of a workpiece to be filled, shown, by way of example, at a rear cavity 405 of a semiconductor substrate 403, wherein the rear cavity 405 has a lateral extension of several millimeters. A metal layer 404 is arranged on a surface of the semiconductor substrate 403 and of the rear cavity 405. By way of example, the metal layer 404 has a thickness of 100 nm. The droplet applicator 401 repeatedly dispenses metal droplets in molten form or molten metal droplets 402 into the rear cavity 405 in order to completely fill the latter. In so doing, the molten metal droplets 402 keep a molten state until impinging on the workpiece and do not solidify until impinging on the workpiece. In other words, when the molten metal droplet impinges on the surface of the metal layer 404 or of the already dispensed molten metal droplets 402, the dispensed metal sinters so that a uniform metal filling with an adjustable porosity forms within the rear cavity 405. Due to the application in the form of a molten liquid and due to the good wetting properties of the liquid phase, slits located at the edge can be completely filled so that a continuous and pore-free connection to the underlying surface is ensured.

In addition, the droplet applicator 101 and 201 and the workpiece to be filled can be arranged in an inert gas atmosphere or in vacuum. In vacuum, cooling of the molten metal droplets during the flight is prevented or slowed. Inert gas atmosphere and vacuum also prevent the oxidation of the melt. In other words, the metal droplets in molten form fall in a targeted manner into the rear cavity 405 and fill it successively to the desired height, here complete filling.

In an exemplary embodiment, the droplet applicator 401 is moved above the rear cavity 405. Alternatively, the workpiece or semiconductor substrate 403 may be moved, wherein the droplet applicator 401 is arranged statically. As a result, there is the possibility to adjust specific angles between the fall curve of the molten metal droplet 402 and the workpiece to be filled so that undercuts can be filled. Preferably, the metal layer comprises the same material as the molten metal droplets, e.g., copper. This improves the wetting properties and the connection of the solidifying copper phase.

In one exemplary embodiment, two droplet applicators with different wire diameters are used. In this case, smaller molten metal droplets can be applied in a first process step so that a first thin coating is produced. In a following step, larger molten metal droplets are generated in order to fill the rear cavity efficiently, quickly and cost-effectively. As a result, the maximum heat input into the workpiece to be filled can be controlled.

In a further exemplary embodiment, several droplet applicators forming a droplet applicator system are used so that several rear cavities can be filled simultaneously. Alternatively, one droplet applicator can fill several rear cavities in layers by scanning the sample, wherein a large surface area can be processed in a short time.

1-10. (canceled)

11. A droplet applicator configured to generate molten metal droplets having a volume in a range of nanoliters to milliliters, the droplet applicator comprising:
a first wire feeding device vertically moving a first wire including a first wire material;
a first wire blocking device configured to block the first wire, wherein the first wire feeding device and the first wire blocking device are arranged within a housing; and
a wire heating device arranged, vertically flush, below the first wire feeding device, wherein the wire heating device heats regions of the first wire that have been introduced into the wire heating device by the first wire feeding device, to a temperature above a melting temperature of the first wire material.

12. The droplet applicator according to claim 11, further comprising:
a second wire feeding device arranged at a horizontal distance from the first wire feeding device, wherein a horizontal direction of the second wire feeding device is arranged perpendicularly to a vertical direction, wherein the second wire feeding device vertically moves a second wire, wherein a diameter of the first wire and a diameter of the second wire are different from one another, and the wire heating device is configured to move horizontally.

13. The droplet applicator according to claim 11, wherein the wire heating device includes an induction coil.

14. The droplet applicator according to claim 11, wherein the wire heating device has a pointed surface that can be heated via an electrical resistance.

15. The droplet applicator according to claim 14, wherein the pointed surface includes tungsten or carbon or ceramic.

16. The droplet applicator according to claim 12, further comprising:
a suction device is arranged within the housing and configured to extract gases that arise during melting of the first wire and/or of the second wire.

17. The droplet applicator according to claim 11, further comprising:
a closure arranged at a vertical distance below the wire heating device, wherein the closure is moveable horizontally.

18. The droplet applicator according to claim 12, wherein the first wire material and/or the second wire material include.

19. The droplet applicator according to claim 11, wherein the droplet applicator is configured to fill a rear cavity of a semiconductor component.

20. A method for generating a molten metal droplet, comprising the following steps:
introducing regions of a first wire made of a first wire material into a wire heating device using a first wire feeding device; and
heating regions of the first wire to a temperature above a melting temperature of the first wire material using the wire heating device, which is operated with a high-frequency alternating field.
